(19) United States
(12) Patent Application Publication
(10) Pub. No.: US 2025/0390642 A1
(43) Pub. Date: Dec. 25, 2025

(54) DYNAMIC EVALUATION METHOD FOR DEFENSIVE RESILIENCE OF MOUNTAINOUS TERRITORIAL SPACE AGAINST GEOLOGICAL DISASTERS

(71) Applicant: Chongqing University, Chongqing (CN)

(72) Inventors: Haijia WEN, Chongqing (CN); Long QIAN, Chongqing (CN); Junhao HUANG, Chongqing (CN); Bo LIU, Chongqing (CN); Jialan ZHANG, Chongqing (CN); Zhuohang LI, Chongqing (CN); Xuekun XIANG, Chongqing (CN)

(21) Appl. No.: 19/230,265

(22) Filed: Jun. 6, 2025

(30) Foreign Application Priority Data
Jun. 25, 2024 (CN) 202410826745.7

(51) Int. Cl. G06F 30/27; G06Q 50/26

(52) U.S. Cl. CPC G06F 30/27; G06Q 50/26

(57) ABSTRACT

Provided is a dynamic evaluation method for defensive resilience of mountainous territorial space against geological disasters, which relates to the technical field of territorial spatial planning. The evolution of geological disasters of slopes and interaction thereof with the territorial space are divided into different stages. Suitable evaluation methods and models such as machine learning are adopted to dynamically quantitatively analyze the defensive resilience levels of the mountainous town systems against the geological disasters of slopes at different stages, and optimized analysis is performed to obtain the complete-period comprehensive resilience of a research region against the geological disasters of slopes. Obstacle degree analysis is also performed to specify the weak links of the defensive resilience of the territorial space of mountainous towns. The method provides reference basis for disaster prevention and planning of the mountainous territorial space and has strong practicability.

### CROSS REFERENCE TO RELATED APPLICATION

This patent application claims the benefit and priority of Chinese Patent Application No. 202410826745.7, filed with the China National Intellectual Property Administration on Jun. 25, 2024, the disclosure of which is incorporated by reference herein in its entirety as part of the present application.

### TECHNICAL FIELD

The present disclosure relates to the technical field of territorial spatial planning, and in particular, to a dynamic evaluation method for defensive resilience of mountainous territorial space against geological disasters.

### BACKGROUND

In recent years, with large-scale resource development, geological disasters have constantly happened, severely threatening the safety of lives and property of local people and also severely harming the sustainable development of the society. Types of geological disasters mainly include collapse, landslide, debris flow, surface subsidence, ground fissure, etc. Geological disasters (collapse, landslide, debris flow) of slopes in mountainous town areas may happen at a high frequency and on a large scale, greatly limiting the development of the social economy. Due to the characteristics of uncertainty and suddenness of the geological disasters of slopes, passive disaster prevention measures cannot meet the requirements of future development of mountainous towns. Urban resilience, as a new idea of urban risk governance, plays an important role in achieving the purposes of preventing and retarding the disaster impact, protecting the safety of lives and property of people, and improving the happiness of living of people. Moreover, the geological disasters are in mutual association and restraint relationships with territorial space, land utilization, resource development, and the like of a mountainous town. The geological disasters restrict the development and utilization of urban space and the development of humanistic economy. Also, the development and utilization of the territorial space will, in turn, affect the occurrence of the geological disasters. Unreasonable development and utilization of the territorial space and land may induce or even aggravate the geological disasters. Perfect and scientific territorial spatial planning can control the sources of geological disasters so as to prevent the geological disasters. In the context of a territorial spatial planning system, “resilient city” is a major means for a mountainous town to cope with disasters in the future, and the construction of the resilient city can effectively reduce the loss scale of the mountainous town in a complex disaster scenario. The planning concept of the resilient city has been widely recognized and needs to be fully fused in territorial spatial planning. In the territorial spatial planning process of China, the resilient planning thought should be introduced into the territorial spatial planning. Therefore, the research on a dynamic evaluation method for defensive resilience of territorial space of mountainous towns to complete periods of geological disasters of slopes provides a new perspective for preventing disasters and reducing damages.

Existing methods for the evaluation of disaster resistant resilience of towns mainly include experiential evaluation systems and semi-empirical semi-quantitative evaluation systems. The evaluation of urban resilience by the experiential evaluation systems is mainly achieved through interviewing by experts or teams on some details of cities, e.g., evaluation systems such as Uscore2 and Asian cities climate change resilience network (ACCCRN). Uscore2 will ask an urban manager whether the urban manager knows disasters a city may face or have undergone, whether a corresponding disaster prevention plan has been established, and so on. The semi-empirical semi-quantitative evaluation systems are mainly configured for scoring according to related indicators of cities and combined calculation according to certain weights to obtain resilience evaluations of cities in various aspects and as a whole, such as disaster resilience score card for cities (DRSC), baseline resilience indicators for communities (BRIC), and city resilience index (CRI). The CRI indicator system, as a typical example, includes 4 dimensions, 12 objectives, and 52 indicators. By quantifying statistical data and answering questions asked, the 52 indicators are scored by 1-5 scores, thereby obtaining city resilience scores in various dimensions and a final city resilience score.

In the traditional resilience evaluation methods, the interaction law between the development and utilization of territorial space and geological disasters is seldom taken into account, and it is hard to perform evaluation from the perspectives of complete periods of geological disasters of slopes and internal differentiated development and utilization of mountainous town space, and subjective qualitative evaluation is mainly adopted with low evaluation efficiency. Moreover, although spatial evaluation analysis is performed on urban resilience in some studies, only static evaluation of resilience is taken into account while the spatial-temporal evolution of the resilience of territorial space of towns due to factors such as changes in climate conditions and rapid development of cities is ignored, and the territorial spatial planning of mountainous towns cannot be effectively supported.

In order to solve the above problems, the present disclosure provides a dynamic evaluation method for defensive resilience of mountainous territorial space against geological disasters.

### SUMMARY

An objective of the present disclosure is to provide a dynamic evaluation method for defensive resilience of mountainous territorial space against geological disasters so as to solve the problems mentioned in the background.

The traditional resilience evaluation methods mainly based on subjective qualitative analysis are low in evaluation efficiency, may be greatly affected by subjective opinions of individuals, and mostly adopt static evaluation which in turns affects the accuracy and reliability of evaluation results.

To achieve the above objective, the present disclosure adopts the following technical solutions:

A dynamic evaluation method for defensive resilience of mountainous territorial space against geological disasters includes the following steps:
S1: obtaining historical data of geological disasters of slopes in a research region and resilience evaluation data of territorial space of mountainous towns, and establishing a defensive resilience database of geological disasters of slopes in the research region;
S2: constructing, using a machine learning algorithm, a defensive resilience evaluation model for geological disasters of slopes for a pre-disaster prevention stage;
S3: constructing, using a subjective and objective combined combination weighting method, a defensive resilience evaluation model for geological disasters of slopes for in-disaster emergency response and post-disaster restoration stages;
S4: evaluating, using a multi-attribute decision-making comprehensive evaluation method, comprehensive resilience of the research region; and
S5: constructing an obstacle degree model based on evaluation and analysis results of S2 to S4 to perform resilience obstacle degree diagnosis, and putting forward a resilience improvement strategy based on a diagnosis result.

Preferably, in S2, optimizing training is performed on the defensive resilience evaluation model for geological disasters of slopes for the pre-disaster prevention stage with the data obtained in S1, and then resilience evaluation of territorial space of mountainous towns at a pre-disaster stage is performed; and dynamic resilience data of the pre-disaster prevention stage from different years is input to obtain a dynamic evaluation result of territorial space defensive resilience at the pre-disaster prevention stage.

Preferably, in the process of performing resilience evaluation of territorial space of mountainous towns at the pre-disaster stage in S2, a possibility of a slope resisting a geological disaster in natural environment in an area to be evaluated is evaluated based on the historical data of geological disasters of slopes and by taking a plurality of evaluation indicators into account; and the defensive resilience evaluation model for geological disasters of slopes for the pre-disaster prevention stage is established and optimized based on the evaluation indicators, and the optimized model is applied.

Preferably, in S3, weights of evaluation indicators for territorial space resilience of mountainous towns at the in-disaster emergency response and post-disaster restoration stages are determined based on the data in S1; and dynamic resilience data of the in-disaster emergency response and post-disaster restoration stages from different years is input to obtain a dynamic evaluation result of territorial space resilience at the in-disaster emergency response and post-disaster restoration stages.

Preferably, in S3, an interaction law between the development and utilization of territorial space and geological disasters is taken into account, and evaluation indicators for territorial space resilience of mountainous towns at the in-disaster emergency response and post-disaster restoration stages are selected for evaluating in-disaster emergency response and post-disaster restoration capabilities.

Preferably, specific steps of determining weights of evaluation indicators for territorial space resilience of mountainous towns at the in-disaster emergency response and post-disaster restoration stages in S3 are as follows:
S3.1: endowing, based on a subjective weighting method, the evaluation indicators for territorial space resilience of mountainous towns at the in-disaster emergency response and post-disaster restoration stages with subjective weights;
S3.2: endowing, based on an objective weighting method, the evaluation indicators for territorial space resilience of mountainous towns at the in-disaster emergency response and post-disaster restoration stages with objective weights; and
S3.3: subjecting the subjective weights and the objective weights to combination weighting based on a combined weight analysis method.

Preferably, in S4, situations with best comprehensive resilience and worst comprehensive resilience are found by calculation according to evaluation results of pre-disaster prevention resilience, in-disaster emergency response resilience, and post-disaster restoration resilience of evaluation units obtained in S2 and S3, and the comprehensive resilience of each evaluation unit is ranked to obtain comprehensive resilience levels of the evaluation units in the research region.

Preferably, in S5, weights of indicators are determined according to an evaluation model for the pre-disaster prevention resilience, the in-disaster emergency response resilience, and the post-disaster restoration resilience of the evaluation units obtained in S2 and S3, obstacle degrees of the evaluation units on the indicators are calculated, and the resilience improvement strategy is put forward according to the analysis result in S4.

Compared with the prior art, the present disclosure provides a dynamic evaluation method for defensive resilience of mountainous territorial space against geological disasters, which has the following beneficial effects.

According to the present disclosure, the geological disasters of slopes are divided into different stages. Suitable evaluation methods and models such as machine learning are adopted to dynamically quantitatively analyze the defensive resilience of the mountainous town system against the geological disasters of slopes at different stages, and optimized analysis is performed to obtain the complete-period comprehensive resilience of the research region against the geological disasters of slopes. Finally, obstacle degree analysis is performed to specify the weak links of the defensive resilience of the territorial space of mountainous towns. The method provides reference basis for the territorial space planning of mountainous towns and has strong practicability.

### BRIEF DESCRIPTION OF THE DRAWINGS

FIG. 1 is a flowchart of a method mentioned in Embodiment 1 of the present disclosure;

FIG. 2 is a schematic diagram showing defensive resilience results of territorial space of mountainous towns at a pre-disaster prevention stage mentioned in Embodiment 2 of the present disclosure;

FIG. 3 is a schematic diagram showing defensive resilience results of territorial space of mountainous towns at in-disaster emergency response and post-disaster restoration stages mentioned in Embodiment 2 of the present disclosure;

FIG. 4 is a schematic diagram showing comprehensive resilience results of territorial space of mountainous towns to complete-period defense of geological disasters of slopes mentioned in Embodiment 2 of the present disclosure; and

FIG. 5 is a schematic diagram showing obstacle degree diagnosis results on defensive resilience of territorial space of mountainous towns to complete-period defense of geological disasters of slopes in Banan district of Chongqing in 2020 mentioned in Embodiment 2 of the present disclosure.

### DETAILED DESCRIPTION OF THE EMBODIMENTS

The technical solutions of the embodiments of the present disclosure are clearly and completely described below with reference to the drawings in the embodiments of the present disclosure. Apparently, the described embodiments are merely a part rather than all of the embodiments of the present disclosure.

According to the present disclosure, the geological disasters of slopes are divided into different stages. Suitable evaluation methods and models such as machine learning are adopted to dynamically quantitatively analyze the defensive resilience of the mountainous town system against the geological disasters of slopes at different stages, and optimized analysis is performed to obtain the complete-period comprehensive resilience of the research region against the geological disasters of slopes. Finally, obstacle degree analysis is performed to specify the weak links of the defensive resilience of the territorial space of mountainous towns. The method provides reference basis for the territorial space planning of mountainous towns and has strong practicability. The present disclosure specifically includes the following contents.

### Embodiment 1

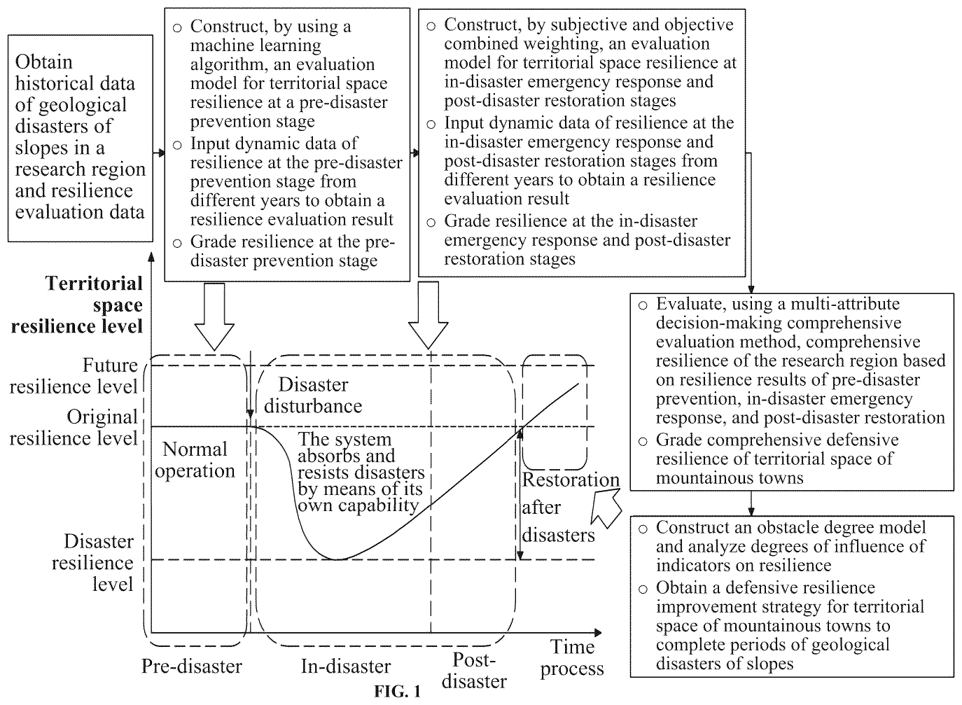

With reference to FIG. 1, a dynamic evaluation method for defensive resilience of mountainous territorial space against geological disasters provided in the present disclosure includes the following steps.

In step S1, historical data of geological disasters of slopes in a research region and resilience evaluation data of territorial space of mountainous towns are obtained, and a defensive resilience database of geological disasters of slopes in the research region is established. Details are as follows.

The defensive resilience database of geological disasters of slopes in the research region includes, but is not limited to, an invariable or slowly varying high-precision digital elevation model (DEM), geological data, dynamically changing hydrological and meteorological, economic development data, social indicator data, infrastructure data, etc.

In step S2, a defensive resilience evaluation model for geological disasters of slopes for a pre-disaster prevention stage is constructed using a machine learning algorithm. Details are as follows.

Optimizing training is performed on the defensive resilience evaluation model for geological disasters of slopes for the pre-disaster prevention stage with the data obtained in S1. As used in this step, the data in the defensive resilience database of geological disasters of slopes in the research region obtained in S1 includes, but is not limited to, elevation, slope gradient, slope orientation, slope position, slope orientation change rate, slope gradient change rate, curvature, topographic relief amplitude, microrelief, roughness of the earth's surface, elevation variance coefficient, surface penetration depth, distances from faults, distances from roads, distances from rivers, lithological characters, soil types, topographic wetness index, average rainfall, land use types, normalized differential vegetation index (NDVI), etc.

The machine learning algorithm includes, but is not limited to, models such as decision-making tree, random forest, support vector machine, artificial neural network, XGBoost, and LightGBM.

Methods for optimizing the machine learning models include, but are not limited to, methods such as algorithm hyperparameter optimization, dominant factor screening, evaluation unit scale selection, sample selection, and proportional sample comparison.

Resilience evaluation of territorial space of mountainous towns at the pre-disaster stage is then performed. Specifically, a possibility of a slope resisting a geological disaster in natural environment in an area to be evaluated is evaluated based on the historical data of geological disasters of slopes and by taking a plurality of evaluation indicators into account; and the defensive resilience evaluation model for geological disasters of slopes for the pre-disaster prevention stage is established and optimized based on the evaluation indicators, and the optimized model is applied.

Dynamic data such as precipitations, land use types, and human activities from different years is input to obtain a dynamic evaluation result of territorial space defensive resilience at the pre-disaster prevention stage.

In step S3, a defensive resilience evaluation model for geological disasters of slopes for in-disaster emergency response and post-disaster restoration stages is constructed using a subjective and objective combined combination weighting method. Details are as follows.

Weights of evaluation indicators for territorial space resilience of mountainous towns at the in-disaster emergency response and post-disaster restoration stages are determined based on the data in S1. An interaction law between the development and utilization of territorial space and geological disasters is taken into account, and evaluation indicators for territorial space resilience of mountainous towns at the in-disaster emergency response and post-disaster restoration stages are selected for evaluating in-disaster emergency response and post-disaster restoration capabilities. The used dynamic data in the defensive resilience database of geological disasters of slopes in the research region obtained in S1 includes, but is not limited to, green coverage ratio, per capita green area, urbanization rate, per capita urban construction land area, per capita road length, per capita water supply pipeline length, per capita gas pipeline length, population density, population of the young and the old, amount of fixed-asset investments, per capita disposal income, per capital gross domestic product (GDP), expenditures for education, expenditures for social security and employment, expenditures for medical care and public health, number of medical and health organizations, number of employed persons in medical and health organizations, number of activities to popularize scientific knowledge of preventing disasters and reducing damages, and density of community residents committees.

Specific steps of determining weights of evaluation indicators for territorial space resilience of mountainous towns at the in-disaster emergency response and post-disaster restoration stages are as follows.

In step S3.1, the evaluation indicators for territorial space resilience of mountainous towns at the in-disaster emergency response and post-disaster restoration stages are endowed with subjective weights based on a subjective weighting method.

In step S3.2, the evaluation indicators for territorial space resilience of mountainous towns at the in-disaster emergency response and post-disaster restoration stages are endowed with objective weights based on an objective weighting method.

In step S3.3, the subjective weights and the objective weights are subjected to combination weighting based on a combined weight analysis method.

Methods for realizing subjective weighting include, but are not limited to, analytic hierarchy process (AHP), delphi method, and link-relative scoring method. Methods for realizing objective weighting include, but are not limited to, entropy weight method, CRITIC method, information quantity weight method, and independent weight method. Methods for realizing combined weight analysis include, but are not limited to, additive synthesis method, multiplicative synthesis method, range maximization, matrix idea, distance function method, and game theory.

Dynamic data such as economic indicators and social indicators from different years is input to obtain a dynamic evaluation result of territorial space resilience at the in-disaster emergency response and post-disaster restoration stages.

In step S4, comprehensive resilience of the research region is evaluated using a multi-attribute decision-making comprehensive evaluation method. Details are as follows.

The used comprehensive evaluation method includes, but is not limited to, technique for order preference by similarity to ideal solution (TOPSIS), grey correlation method, rank-sum ratio (RSR) method, and vlsekriterijumska optimizacija kompromisno resenje (VIKOR). Situations with best comprehensive resilience and worst comprehensive resilience are found by calculation according to evaluation results of pre-disaster prevention resilience, in-disaster emergency response resilience, and post-disaster restoration resilience of evaluation units obtained in S2 and S3, and the comprehensive resilience of each evaluation unit is ranked. A division method for resilience levels may be selected according to an actual situation. Common methods include, but are not limited to, expert experience method, natural break method, geometric margin, classification at equal intervals, and quantile. As a result, comprehensive resilience levels of the evaluation units in the research region are obtained.

In step S5, an obstacle degree model is constructed based on evaluation and analysis results of S2 to S4 to perform resilience obstacle degree diagnosis, and a resilience improvement strategy is put forward based on a diagnosis result. Details are as follows.

Weights of indicators are determined according to an evaluation model for the pre-disaster prevention resilience, the in-disaster emergency response resilience, and the post-disaster restoration resilience of the evaluation units obtained in S2 and S3. Methods for obtaining weights of evaluation indicators required to construct the obstacle degree model include, but are not limited to, geographic detector method, Spearman correlation analysis, shapley additive explanations (SHAP) machine learning explainable analysis, and combined weight analysis. Obstacle degrees of the evaluation units on the indicators are calculated, and the resilience improvement strategy is put forward according to the analysis result in S4. The higher the obstacle degree, the greater the degree of influence of the indicator on resilience.

### Embodiment 2

This embodiment is set forth by taking resilience evaluation of Chongqing in 2020 as an example.

In step S1, historical data of geological disasters of slopes in Chongqing in 2010 to 2019 and resilience evaluation data of territorial space of mountainous towns are obtained, and imported to ArcGIS software for layering processing and reclassification, and a defensive resilience database of geological disasters of slopes in the research region is established.

The established defensive resilience database of geological disasters of slopes in the research region includes, but is not limited to, an invariable or slowly varying high-precision digital elevation model (DEM), geological data, dynamically changing hydrological and meteorological, economic data, and social indicator data. By using the ArcGIS software to perform reclassification and preprocessing, data errors can be reduced, and the accuracy of the evaluation result of the resilience model can be improved. Based on the high-precision digital elevation model (DEM) of the research region, the perfect geographic space processing tool of the ArcGIS software is used so that the accuracy and efficiency of analysis can be guaranteed to the maximum extent.

In step S2, optimizing training is performed on the defensive resilience evaluation model for geological disasters of slopes for the pre-disaster prevention stage based on the data of the defensive resilience database of geological disasters of slopes of Chongqing in 2010 to 2019 obtained in S1, and then defensive resilience evaluation of territorial space of mountainous towns at the pre-disaster stage is performed. Dynamic data such as precipitations, land use types, and NDVI of Chongqing in 2020 is input to obtain an evaluation result of territorial space resilience at the pre-disaster stage. The machine learning algorithm of this embodiment is the random forest algorithm. The applicability and prediction performance of the random forest algorithm have been proven in existing evaluation researches on susceptibility and dangerousness of geological disasters of slopes. By performing optimizing training on the machine learning model, the model performance can be improved to the maximum extent, and the reliability and accuracy of resilience evaluation can be improved. This embodiment involves optimization of random forest parameters mtry and ntree by iteration to determine optimal values thereof. Moreover, the model prediction performance is obtained by two training sample selection methods, i.e., comparative random selection and 10-fold cross-validation, and the model with a better effect is selected as the final evaluation result.

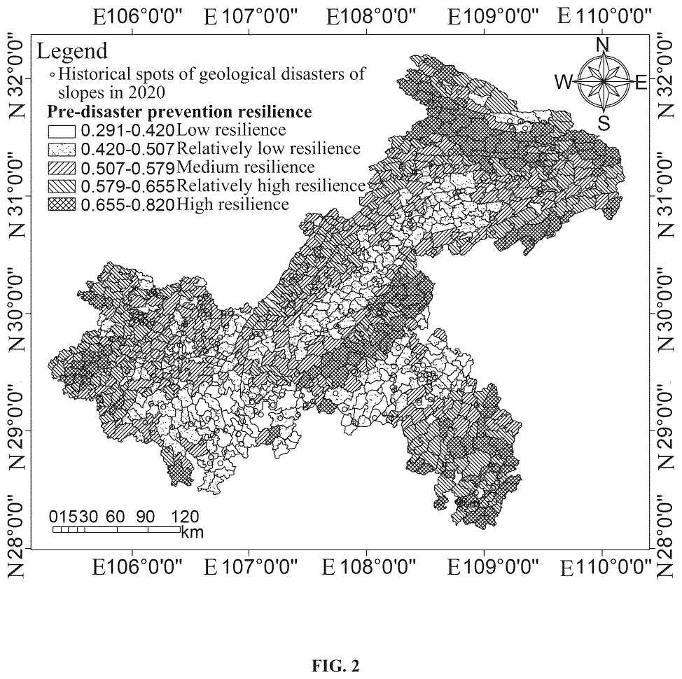

Resilience grading is performed on the resilience evaluation structure of the research region using a reasonable threshold division method, and the resilience space distribution of the whole region can be obtained visually. The pre-disaster emergency response resilience grading method in this embodiment is the natural break method in the ArcGIS software. The pre-disaster prevention resilience is graded into 5 levels by the natural break method, i.e., high resilience, relatively high resilience, medium resilience, lower resilience, and low resilience, in a descending order. The resilience evaluation result of the pre-disaster stage is as shown in FIG. 2.

In step S3, weights of evaluation indicators for territorial space resilience of mountainous towns at the in-disaster emergency response and post-disaster restoration stages are determined with the dynamic data of the defensive resilience database of geological disasters of slopes of Chongqing in 2010 to 2019 obtained in S1. Dynamic data such as related economic indicators and social indicators of Chongqing in 2020 is input to obtain an evaluation result of territorial space resilience at the in-disaster emergency response and post-disaster restoration stages.

In this embodiment, the subjective weighting method is selected to be the analytic hierarchy process, and the objective weighting method is selected to be the entropy weight method. Major steps of determining the weights of the indicators by the analytic hierarchy process are as follows.
1. A hierarchical structure model is established.
2. A discrimination matrix is constructed, and even two of criteria are compared to determine a relative importance degree therebetween.
3. Weight calculation is performed, and an approximate solution to a maximum feature vector is used as a weight value of the discrimination matrix.
4. Consistency is checked.

Major steps of determining the weights of the indicators by the entropy weight method are as follows.
1. Data is standardized.
2. Proportions of samples under the indicators are calculated, and regarded as probabilities used in relative entropy calculation.
3. An information entropy of each indicator is calculated, and an information utility value is calculated, and an entropy weight of each indicator is obtained by normalization.

Since weights of influencing factors obtained using the analytic hierarchy process are affected by the expert experience, the subjectivity is strong, and there is a subjective bias or a risk of man-made repulsion to some indicators. As a result, these weights are not convincing. If objective weights of the influencing factors are determined by using only the entropy weight method, the practical significance of part of the influencing factors might be ignored, and the value determination of practical problems cannot be taken into account.

Therefore, this study uses the multiplicative synthesis method to perform combination weighting with the analytic hierarchy process and the entropy weight method, with a calculation formula as follows:

$${w}_{i} = \frac{{w}_{i}^{a} {w}_{i}^{b}}{{\sum }_{i = 1}^{n} {w}_{i}^{a} {w}_{i}^{b}} ( i = 1 , 2 , … , n )$$

where wᵢ represents a combined weight;

$${w}_{i}^{a}$$

represents a subjective weight of a resilience indicator obtained by the analytic hierarchy process; and

$${w}_{i}^{b}$$

represents an objective weight of the resilience indicator calculated by the entropy weight method.

By combining the subjective analytic hierarchy process and the objective entropy weight method, the subjective bias and the objective one-sidedness of resilience evaluation are eliminated, and the actual situations of anti-disaster resilience of mountainous towns to geological disasters of slopes at the in-disaster emergency response and post-disaster restoration stages in the research region can be reflected truly, objectively, completely, and accurately.

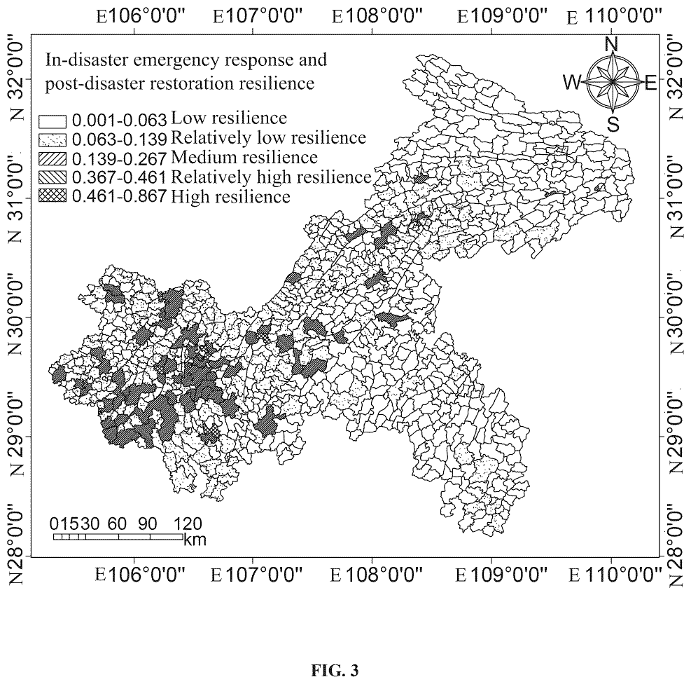

The resilience evaluation indicators are endowed with corresponding weight values, and then a superposition operation is performed on the resilience evaluation indicators to obtain the evaluation result of territorial space resilience of mountainous towns at the in-disaster emergency response and post-disaster restoration stages, as shown in FIG. 3.

In step S4: the comprehensive resilience of the research region is evaluated by selecting the technique for order preference by similarity to ideal solution (TOPSIS) as a comprehensive evaluation method. Major steps of evaluating the comprehensive resilience of the research region by TOPSIS are as follows.
1. An original matrix is oriented toward a forward direction, and research data is unified to an extremely large indicator.
2. The forward matrix is standardized.
3. Distances of evaluation objects from a maximum and a minimum are calculated, and scores are calculated and normalized.
4. Solutions are ranked in a descending order by scores of the evaluation objects to obtain a ranking result of the evaluation objects from good to bad.

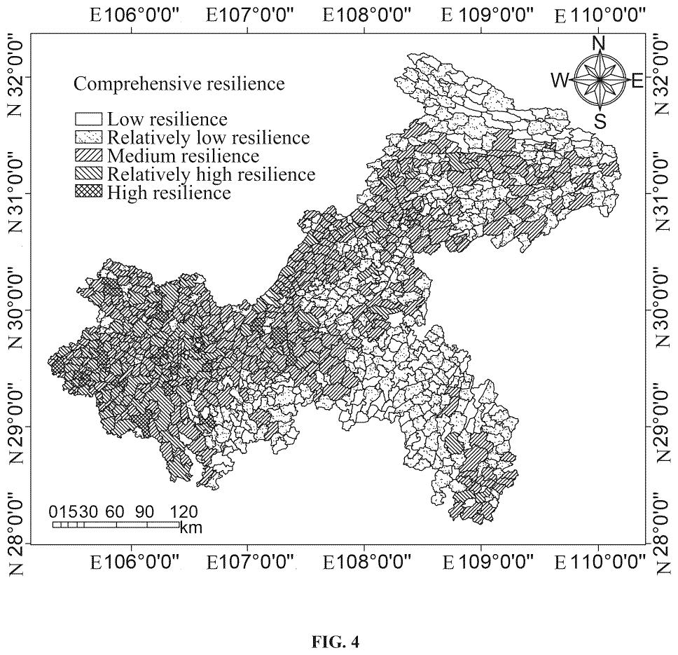

In this embodiment, the comprehensive resilience evaluation results are divided by the natural break method into five levels, i.e., high resilience, relatively high resilience, medium resilience, lower resilience, and low resilience. The resulting comprehensive resilience of the territorial space of the mountainous towns is as shown in FIG. 4.

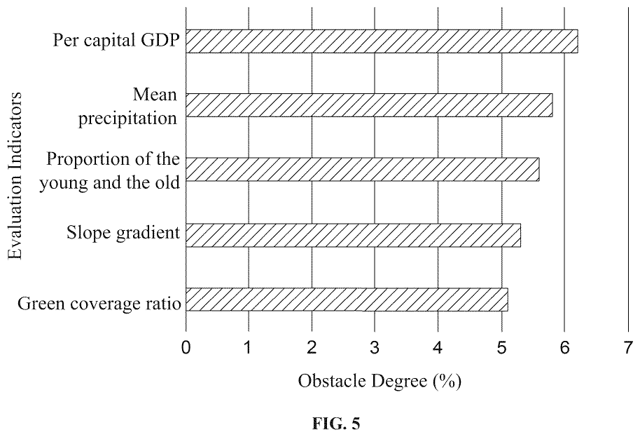

In step S5, using the geographic detector method in this embodiment, factor detection results are normalized to determine the weights of the indicators, and then obstacle degrees of the evaluation units on the indicators are calculated. The higher the obstacle degree, the greater the degree of influence of the indicator on resilience. A resilience improvement strategy is hereby put forward. Taking the obstacle degree diagnosis result of Banan district of Chongqing in this embodiment as an example, FIG. 5 shows top five evaluation indicators in terms of resilience obstacle degree of Banan district. From the obstacle degree diagnosis result, per capital GDP has the greatest influence on the territorial space resilience of Banan district, followed by the annual mean precipitation.

In conclusion, the ArcGIS software is employed in this embodiment to extract the digital elevation model of the research region and preprocess the geographic information data to establish the defensive resilience database of geological disasters of slopes in the research region. Then, the dynamic evaluation model for territorial space resilience of mountainous towns for the pre-disaster stage of geological disasters of slopes is constructed using the random forest machine learning algorithm. Next, the dynamic evaluation model for territorial space resilience of mountainous towns for the in-disaster and post-disaster stages is constructed using the analytic hierarchy process-entropy weight method combined weighting method. Subsequently, the comprehensive resilience model of territorial space of mountainous towns is constructed using TOPSIS. Finally, the weights of the indicators are determined using the geographic detector method, and the obstacle degree model is constructed, providing the dynamic evaluation method for defensive resilience of territorial space of towns to the complete periods of geological disasters of slopes. This method can dynamically quantitatively analyze the resilience of the mountainous town system against the geological disasters of slopes at different stages, and optimized analysis is performed to obtain the complete-period comprehensive resilience of the research region against the geological disasters of slopes. Finally, obstacle degree analysis is performed to specify the weak links of the defensive resilience of the territorial space of mountainous towns. The method provides reference basis for the territorial space planning of mountainous towns and has strong practicability.

The foregoing are merely descriptions of preferred specific implementations of the present disclosure, but the protection scope of the present disclosure is not limited thereto. Any equivalent replacement or modification made within the technical scope of the present disclosure by a person skilled in the art according to the technical solutions of the present disclosure and inventive concepts thereof shall fall within the protection scope of the present disclosure.

What is claimed is:

1. A dynamic evaluation method for defensive resilience of mountainous territorial space against geological disasters, comprising the following steps:
S1: obtaining historical data of geological disasters of slopes in a research region and resilience evaluation data of territorial space of mountainous towns, and establishing a defensive resilience database of geological disasters of slopes in the research region;
S2: constructing, using a machine learning algorithm, a defensive resilience evaluation model for geological disasters of slopes for a pre-disaster prevention stage;
S3: constructing, using a subjective and objective combined combination weighting method, a defensive resilience evaluation model for geological disasters of slopes for in-disaster emergency response and post-disaster restoration stages;
S4: evaluating, using a multi-attribute decision-making comprehensive evaluation method, comprehensive resilience of the research region; and
S5: constructing an obstacle degree model based on evaluation and analysis results of S2 to S4 to perform resilience obstacle degree diagnosis, and putting forward a resilience improvement strategy based on a diagnosis result.

2. The dynamic evaluation method for defensive resilience of mountainous territorial space against geological disasters according to claim 1, wherein in S2, optimizing training is performed on the defensive resilience evaluation model for geological disasters of slopes for the pre-disaster prevention stage with the data obtained in S1, and then resilience evaluation of territorial space of mountainous towns at a pre-disaster stage is performed; and dynamic resilience data of the pre-disaster prevention stage from different years is input to obtain a dynamic evaluation result of territorial space defensive resilience at the pre-disaster prevention stage.

3. The dynamic evaluation method for defensive resilience of mountainous territorial space against geological disasters according to claim 2, wherein in the process of performing resilience evaluation of territorial space of mountainous towns at the pre-disaster stage in S2, a possibility of a slope resisting a geological disaster in natural environment in an area to be evaluated is evaluated based on the historical data of geological disasters of slopes and by taking a plurality of evaluation indicators into account; and the defensive resilience evaluation model for geological disasters of slopes for the pre-disaster prevention stage is established and optimized based on the evaluation indicators, and the optimized model is applied.

4. The dynamic evaluation method for defensive resilience of mountainous territorial space against geological disasters according to claim 1, wherein in S3, weights of evaluation indicators for territorial space resilience of mountainous towns at the in-disaster emergency response and post-disaster restoration stages are determined based on the data in S1; and dynamic resilience data of the in-disaster emergency response and post-disaster restoration stages from different years is input to obtain a dynamic evaluation result of territorial space resilience at the in-disaster emergency response and post-disaster restoration stages.

5. The dynamic evaluation method for defensive resilience of mountainous territorial space against geological disasters according to claim 4, wherein in S3, an interaction law between the development and utilization of territorial space and geological disasters is taken into account, and evaluation indicators for territorial space resilience of mountainous towns at the in-disaster emergency response and post-disaster restoration stages are selected for evaluating in-disaster emergency response and post-disaster restoration capabilities.

6. The dynamic evaluation method for defensive resilience of mountainous territorial space against geological disasters according to claim 5, wherein specific steps of determining weights of evaluation indicators for territorial space resilience of mountainous towns at the in-disaster emergency response and post-disaster restoration stages in S3 are as follows:
S3.1: endowing, based on a subjective weighting method, the evaluation indicators for territorial space resilience of mountainous towns at the in-disaster emergency response and post-disaster restoration stages with subjective weights;
S3.2: endowing, based on an objective weighting method, the evaluation indicators for territorial space resilience of mountainous towns at the in-disaster emergency response and post-disaster restoration stages with objective weights; and
S3.3: subjecting the subjective weights and the objective weights to combination weighting based on a combined weight analysis method.

7. The dynamic evaluation method for defensive resilience of mountainous territorial space against geological disasters according to claim 1, wherein in S4, situations with best comprehensive resilience and worst comprehensive resilience are found by calculation according to evaluation results of pre-disaster prevention resilience, in-disaster emergency response resilience, and post-disaster restoration resilience of evaluation units obtained in S2 and S3, and the comprehensive resilience of each evaluation unit is ranked to obtain comprehensive resilience levels of the evaluation units in the research region.

8. The dynamic evaluation method for defensive resilience of mountainous territorial space against geological disasters according to claim 7, wherein in S5, weights of indicators are determined according to an evaluation model for the pre-disaster prevention resilience, the in-disaster emergency response resilience, and the post-disaster restoration resilience of the evaluation units obtained in S2 and S3, obstacle degrees of the evaluation units on the indicators are calculated, and the resilience improvement strategy is put forward according to the analysis result in S4.
